(19) United States
(12) Patent Application Publication
(10) Pub. No.: US 2025/0218153 A1
(43) Pub. Date: Jul. 3, 2025

(54) PROCESSING CIRCUIT AND TEMPLATE MATCHING METHOD

(71) Applicant: Nuvoton Technology Corporation, Hsinchu Science Park (TW)

(72) Inventors: Wei-Zong CHEN, Taoyuan City (TW); Chun-Hao HUANG, Hsinchu City (TW); Tzu-Lan SHEN, Taoyuan City (TW)

(21) Appl. No.: 18/983,983

(22) Filed: Dec. 17, 2024

(30) Foreign Application Priority Data
Dec. 27, 2023 (TW) 112150951

(51) Int. Cl. G06V 10/75; G06T 3/40; G06T 7/11; H04N 25/772

(52) U.S. Cl. CPC G06V 10/751; G06T 3/40; G06T 7/11; H04N 25/772

(57) ABSTRACT

A processing circuit is provided. The processing circuit includes an image-providing device, an adjustment device, a resistive memory, and a control circuit. The image-providing device is configured to provide a target image. The adjustment device adjusts the scale of a template image to generate a sample image according to the setting information. The resistive memory includes a storage region and a computation circuit. The storage region stores the target image. The computation circuit computes the sample image and the target image to generate a plurality of computation results. The control circuit finds a matching position that matches the sample image in the target image according to the computation results.

### CROSS REFERENCE TO RELATED APPLICATIONS

This application claims priority of Taiwan Patent Application No. 112150951, filed on Dec. 27, 2023, the entirety of which is incorporated by reference herein.

### BACKGROUND OF THE INVENTION

### Field of the Invention

The present invention relates to a processing circuit, and, in particular, to a processing circuit that performs a template matching operation.

### Description of the Related Art

With the advancement of science and technology, there are more and more types and functions of electronic devices. Most electronic devices have memory to store data. Generally, the data in the memory will be read and loaded into a computing unit (independent of the memory) for calculation. However, the movement and transmission of data increases the power consumption of electronic devices and adds additional processing time.

### BRIEF SUMMARY OF THE INVENTION

In accordance with an embodiment of the disclosure, a processing circuit comprises an image-providing device, an adjustment device, a resistive memory, and a control circuit. The image-providing device is configured to provide a target image. The adjustment device adjusts the scale of a template image to generate a sample image according to setting information. The resistive memory comprises a storage region and a computation circuit. The storage region stores the target image. The computation circuit computes the sample image and the target image to generate a plurality of computation results. The control circuit finds a matching position that matches the sample image in the target image according to the computation results.

A template matching method for a resistive memory is provided. An exemplary embodiment of the template matching method is described in the following paragraph. The scale of a template image is adjusted to generate a sample image. A target image is stored in a storage region of the resistive memory. The target image is split to generate a plurality of sub-images. The sample image and the sub-images are computed to generate a plurality of computation results. A matching position that matches the sample image in the target image is found according to the computation results.

Template matching methods may be practiced by the systems which have hardware or firmware capable of performing particular functions and may take the form of program code embodied in a tangible media. When the program code is loaded into and executed by an electronic device, a processor, a computer or a machine, the electronic device, the processor, the computer or the machine becomes a processing circuit for practicing the disclosed method.

### BRIEF DESCRIPTION OF THE DRAWINGS

The present invention can be more fully understood by reading the subsequent detailed description and examples with references made to the accompanying drawings, wherein:

FIG. 1 is a schematic diagram of an exemplary embodiment of a processing circuit according to various aspects of the present disclosure.

FIG. 2 is a schematic diagram of an exemplary embodiment of how a resistive memory splits a storage region according to various aspects of the present disclosure.

FIG. 3 is a schematic diagram of another exemplary embodiment of how a resistive memory splits a storage region according to various aspects of the present disclosure.

FIG. 4 is a schematic diagram of an exemplary embodiment of a resistive memory according to various aspects of the present disclosure.

FIG. 5 is a flowchart of an exemplary embodiment of a template matching method according to various aspects of the present disclosure.

### DETAILED DESCRIPTION OF THE INVENTION

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

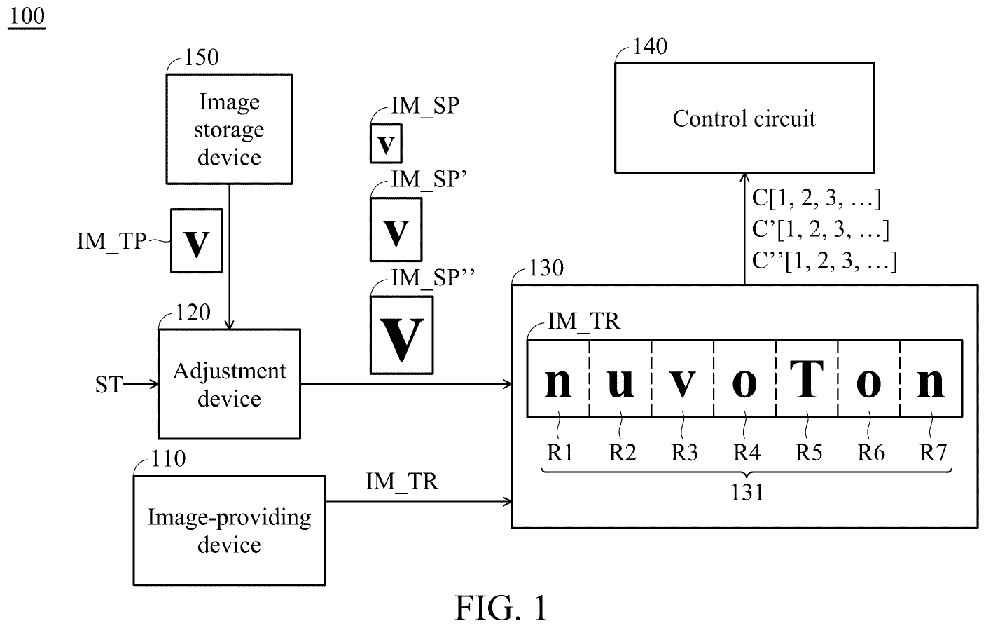

FIG. 1 is a schematic diagram of an exemplary embodiment of a processing circuit according to various aspects of the present disclosure. The processing circuit 100 comprises an image-providing device 110, an adjustment device 120, a resistive memory (ReRAM) 130, and a control circuit 140. The structure of the processing circuit 100 is not limited in the present disclosure. In one embodiment, the processing circuit 100 is a micro-controller unit (MCU) or a micro-processor unit (MPU).

The image-providing device 110 is configured to provide a target image IM_TR. The type of the image-providing device 110 is not limited in the present disclosure. In one embodiment, the image-providing device 110 comprises an image sensor, such as complementary metal-oxide semiconductor (CMOS) or a charge-coupled device (CCD). In this case, the target image IM_TR is a sensing result of the image-providing device 110. In another embodiment, the image-providing device 110 is a memory, such as a SRAM. In this case, the target image IM_TR is stored in the image-providing device 110.

In some embodiments, the processing circuit 100 further comprises an image storage device 150. The image storage device 150 provides a template image IM_TP. The kind of the image storage device 150 is not limited in the present disclosure. In one embodiment, the image storage device 150 is a memory, such as a SRAM.

The adjustment device 120 adjusts the scale of the template image IM_TP according to the setting information ST to generate a sample image IM_SP. The adjustment device 120 generates different sample images according to different setting information. In one embodiment, the adjustment device 120 further generates sample images IM_SP′ and IM_SP″. The scale of the sample image IM_SP is smaller than the scale of the sample image IM_SP′. The scale of the sample image IM_SP′ is smaller than the scale of the sample image IM_SP″. In one embodiment, the scale of one of the sample images IM_SP, IM_SP′, and IM_SP″ is the same as the scale of the template image IM_TP. In some embodiments, the adjustment device 120 provides at least one sample image (such as at least one of IM_SP˜IM_SP″) according to the setting information ST.

The resistive memory 130 stores the target image IM_TR and performs a template matching operation for at least one of the sample images IM_SP, IM_SP′, and IM_SP″ with the template image IM_TP. Since the resistive memory 130 has the advantages of excellent storage density, low power consumption, and fast writing, the efficiency of the template matching operation can be improved. Furthermore, since the template matching operation is performed directly in the resistive memory 130, there is no need to load the target image IM_TR stored in the resistive memory 130 into an external computing unit for processing, thereby avoiding the movement and transmission of data and reducing the power consumption of processing circuit 100

In one embodiment, the resistive memory 130 stores the target image IM_TR in a storage region 131. The storage region 131 comprises image regions R1˜R7. The image regions R1˜R7 have the same size. The image regions R1˜R7 do not overlap each other, but the disclosure is not limited thereto. In other embodiments, at least one of the image regions R1˜R7 overlaps adjacent image regions. The resistive memory 130 computes the sample image IM_SP with the images which are stored in the image regions R1˜R7 to generate a plurality of computation results C[1,2,3, . . . ].

The control circuit 140 determines whether there is an image that most matches the sample image IM_SP in the target image IM_TR according to the computation result C[1,2,3, . . . ]. For example, if each operation value of the computation results C[1,2,3, . . . ] is lower than a threshold value, it means that there is no image that most matches the sample image IM_SP in the target image IM_TR.

In other embodiments, the resistive memory 130 further computes the sample image IM_SP′ and each image of the image regions R1˜R7 to generate a plurality of computation results C′ [1,2,3, . . . ], and computes the sample image IM_SP″ and each image of the image regions R1˜R7 to generate a plurality of computation results C″ [1,2,3, . . . ]. The number of operation values for each computation result. The number of operation values of one of the computation results C[1,2,3, . . . ], C′ [1,2,3, . . . ] and C″ [1,2,3, . . . ] may be the same or different from the other.

The control circuit 140 determines whether an image that is in the target image IM_TR and matches the sample image IM_SP, IM_SP′, or IM_SP″ according to the computation results C[1,2,3, . . . ], C′ [1,2,3, . . . ], and C″ [1,2,3, . . . ]. In one embodiment, the control circuit 140 ranks the set of all computation results to find the most matching image in the target image IM_TR, thereby achieving the positioning function. For example, the control circuit 140 obtains that the image (v) in the image region R3 is most similar to the sample image IM_SP′ according to the computation results C[1,2,3, . . . ], C′ [1,2,3, . . . ], and C″ [1,2,3, . . . ].

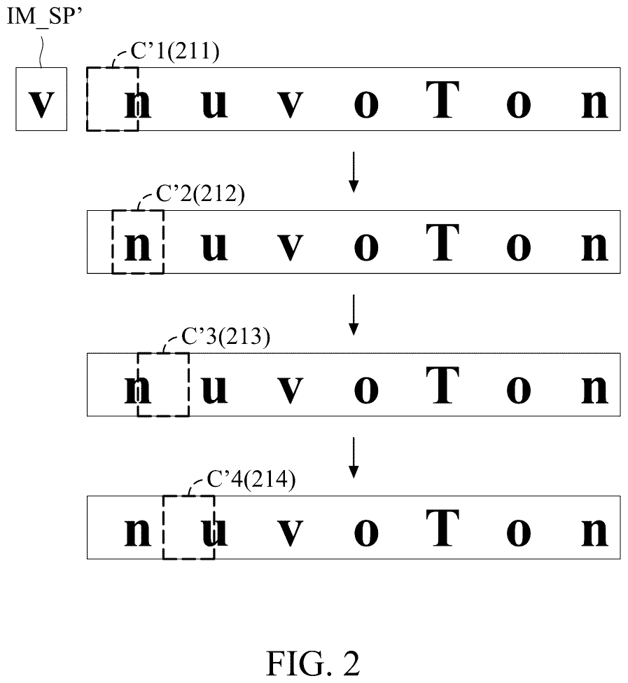

In other embodiments, the resistive memory 130 splits the storage region 131 according to the setting information ST and computes the images stored in the split regions with the sample image. FIG. 2 is a schematic diagram of an exemplary embodiment of how the resistive memory 130 splits the storage region 131. In this embodiment, the resistive memory 130 horizontally splits the storage region 131 into image regions. For brevity, FIG. 2 only shows image regions 211˜214. The image regions 211˜214 overlap adjacent image regions. For example, the image region 211 overlaps the image region 212, and the image region 212 overlaps the image regions 211 and 213. In this case, the image regions 211˜214 have the same size. In other embodiments, the number of pixels in the image stored in each of the image regions 211˜214 is the same as the number of pixels in the sample image IM_SP′. For example, if the number of pixels in the sample image IM_SP′ is 6×4, the number of pixels in the image stored in each of the image regions 211˜214 is also 6×4.

The resistive memory 130 selects the image region 211 and computes the sample image IM_SP′ and the image stored in the image region 211 to generate an computation result C′1. Then, the resistive memory 130 selects the image region 212 and computes the sample image IM_SP′ and the image stored in the image region 212 to generate an computation result C′2. Next, the resistive memory 130 selects the image region 213 and computes the sample image IM_SP′ and the image stored in the image region 213 to generate an computation result C′3. Then, the resistive memory 130 selects the image region 214 and computes the sample image IM_SP′ and the image stored in the image region 214 to generate an computation result C′4. After computing all image regions, the resistive memory 130 integrates all computation results C′1˜C′4 and outputs the integrated result (e.g., C′ [1,2,3, . . . ]. In some embodiments, the number of computation results is the same as the number of pixels in the sample image IM_SP′. For example, assume that the number of pixels in the sample image IM_SP′ is 6×4. In this case, the number of computation results is also 6×4.

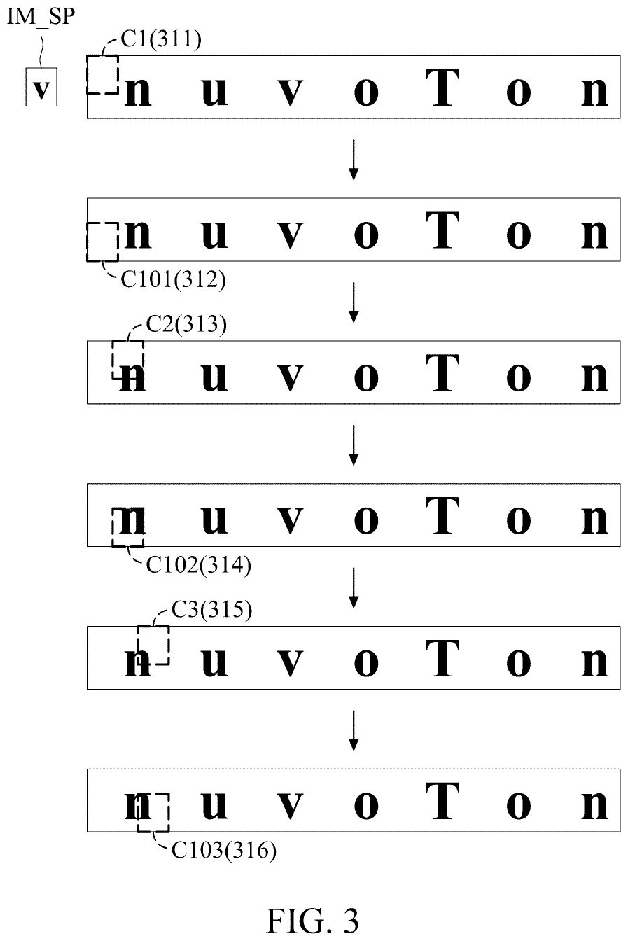

FIG. 3 is a schematic diagram of another exemplary embodiment of how the resistive memory 130 splits the storage region 131 according to various aspects of the present disclosure. In this case, the resistive memory 130 horizontally splits storage region 131 to generate a plurality of image regions. For brevity, FIG. 3 only shows image regions 311˜316. The image regions 311˜316 overlap adjacent image regions. For example, the image region 311 overlaps the image regions 312˜314, and the image region 313 overlaps the image regions 311, 312, and 314˜316. In this case, the image regions 311˜316 have the same size. In other embodiments, the number of pixels in the image stored in each of the image regions 311˜316 is the same as the number of pixels in the sample image IM_SP.

The resistive memory 130 selects the image region 311 and computes the sample image IM_SP and the image stored in the image region 311 to generate an computation result C1. Then, the resistive memory 130 selects the image region 312 and computes the sample image IM_SP and the image stored in the image region 312 to generate an computation result C101. Next, the resistive memory 130 selects the image region 313 and computes the sample image IM_SP and the image stored in the image region 313 to generate an computation result C2. Then, the resistive memory 130 selects the image region 314 and computes the sample image IM_SP and the image stored in the image region 314 to generate an computation result C102. Next, the resistive memory 130 selects the image region 315 and computes the sample image IM_SP and the image stored in the image region 315 to generate an computation result C3. Then, the resistive memory 130 selects the image region 316 and computes the sample image IM_SP and the image stored in the image region 316 to generate an computation result C103. After computing all image regions, the resistive memory 130 integrates all computation results C1, C101, C2, C102, C3, and C103 and outputs the integrated result (e.g., C[1,2,3, . . . ].

The present disclosure does not limit how the resistive memory 130 computes the sample image and the target image. In one embodiment, the resistive memory 130 performs a multiplication operation on the sample image and the target image. Taking the sample image IM_SP′ as an example, it is assumed that the size of the sample image IM_SP′ is as in equation (1).

$$[ \begin{matrix}{V}_{0} \\ {V}_{1} \\ {V}_{2} \\ {V}_{3}\end{matrix} ] \qquad ( 1 )$$

Assume that the number of pixels in the target image IM_TR is 4×4, as follows:

$$[ \begin{matrix}{G}_{00} {G}_{01} {G}_{02} {G}_{03} \\ {G}_{10} {G}_{11} {G}_{12} {G}_{13} \\ {G}_{20} {G}_{21} {G}_{22} {G}_{23} \\ {G}_{30} {G}_{31} {G}_{32} {G}_{33}\end{matrix} ] \qquad ( 2 )$$

After computing equations (1) and (2) by the resistive memory 130, the computed results are as follows:

$$[ \begin{matrix}{I}_{0} \\ {I}_{1} \\ {I}_{2} \\ {I}_{3}\end{matrix} ] \qquad ( 3 )$$

The control circuit 140 obtains whether the target image IM_TR has an image that matches with the sample image IM_SP′ according to equation (3).

By utilizing the high speed and low power consumption characteristics of the resistive memory 130, the template matching operation of image processing is performed. In the template matching operation, correlation is used as a feature measurement method to measure the similarity between the sample image and the target image. The characteristics of the resistive memory 130 are utilized to achieve fast feature extraction and correlation calculation. The image features are efficiently computed by the resistive memory 130. The resistive memory 130 determines the best matching image region according to the computation results. In some embodiment, the control circuit 140 achieves a positioning according to the computation results of the resistive memory 130. The control circuit 140 can determine the flow and number of people in a specific space according to the computation results of the resistive memory 130. For example, the control circuit 140 performs inference operations and learning operations according to the computation results of the resistive memory 130 to perform artificial intelligence (AI) analysis, such as image positioning, tracking, or text extraction from pictures. Since the resistive memory 130 has fast computing speed, the control circuit 140 can quickly perform image judgment and improve the AI analysis speed.

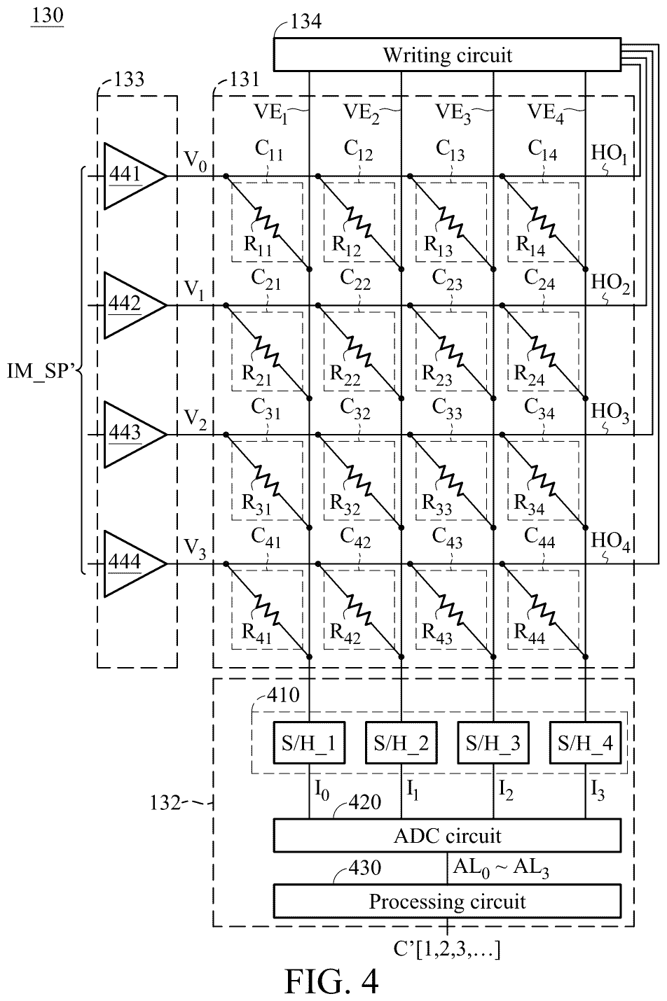

FIG. 4 is a schematic diagram of an exemplary embodiment of the resistive memory 130 according to various aspects of the present disclosure. The resistive memory 130 comprises the storage region 131, a computation circuit 132, and a writing circuit 134. The writing circuit 134 writes the target image IM_TR to the storage region 131. In some embodiments, the storage region 131 comprises transmission lines VE₁˜VE₄, HO₁˜HO₄, and memory cells C₁₁˜C₄₄, but the disclosure is not limited thereto. In other embodiments, the storage region 131 comprises any suitable number of transmission lines and memory cells. Each of the memory cells C₁₁˜C₄₄ is coupled between two transmission lines. For example, the memory cell C₁₁ is coupled between the transmission lines HO₁ and VE₁, and the memory cell C₁₂ is coupled between the transmission lines HO₁ and VE₂.

In one embodiment, each of the memory cells C₁₁˜C₄₄ comprises a resistor layer to store the gray-level of one pixel of the target image IM_TR. For example, the writing circuit 134 transforms the gray-levels of all pixels of the target image IM_TR into corresponding voltage values and provides the voltage values to the memory cells C₁₁˜C₄₄ to set the resistances of the resistor layers of the memory cells C₁₁˜C₄₄. In this case, the resistance of each resistor layer is related to the gray-level of a corresponding pixel. For example, the resistance of the resistor layer R₁₁ of the memory cell C₁₁ is related to the gray-level (such as the value 0) of a first pixel of the target image IM_TR, and the resistance of the resistor layer R₁₂ of the memory cell C₁₂ is related to the gray-level (such as the value 205) of a second pixel of the target image IM_TR.

The computation circuit 132 computes the sample image IM_SP″ and the target image IM_TR stored in the storage region 131 to generate the computation results C′ [1,2,3, . . . ]. The structure of the computation circuit 132 is not limited in the present disclosure. In one embodiment, the computation circuit 132 comprises a sample-hold circuit 410, an analog-to-digital convertor (ADC) circuit 420, and a processing circuit 430. The sample-hold circuit 410 is coupled to the transmission lines VE₁˜VE₄ and generates sampling signals I₀˜I₃.

In one embodiment, the sample-hold circuit 410 comprises sample-hold devices S/H_1˜S/H_4. The sample-hold device S/H_1 samples and holds the signal of the transmission line VE₁ to provide the sampling signal I₀. The sample-hold device S/H_2 samples and holds the signal of the transmission line VE₂ to provide the sampling signal I₁. The sample-hold device S/H_3 samples and holds the signal of the transmission line VE₃ to provide the sampling signal I₂. The sample-hold device S/H_4 samples and holds the signal of the transmission line VE₄ to provide the sampling signal I₃.

The ADC circuit 420 converts the sampling signals I₀˜I₃ to generate digital signals AL₀˜AL₃. In this embodiment, the ADC circuit 420 converts the sampling signals I₀˜I₃ from an analog format into a digital format and serves the converted results as the digital signals AL₀˜AL₃. The processing circuit 430 accumulates the digital signals AL₀˜AL₃ to generate the computation results C′ [1,2,3, . . . ].

In other embodiments, the resistive memory 130 further comprises a digital-to analog converter (DAC) circuit 133. The DAC circuit 133 converts the gray-levels of the sample image IM_SP′ to generate analog signals V₀˜V₃ and provides the analog signals V₀˜V₃ to the transmission lines HO₁˜HO₄. In this embodiment, the DAC circuit 133 comprises DACs 441˜444. The DACs 441˜444 are coupled to the transmission lines HO₁˜HO₄, respectively.

In some embodiments, the number (e.g., 4×4) of pixels of the target image in the storage area 131 is larger than the number (e.g., 4) of pixels of the sample image IM_SP′. Additionally, the number of digital signals AL₀˜AL₃ is the same as the number of pixels in the sample image IM_SP′. The number of analog signals V₀˜V₃ is also the same as the number of pixels in the sample image IM_SP′.

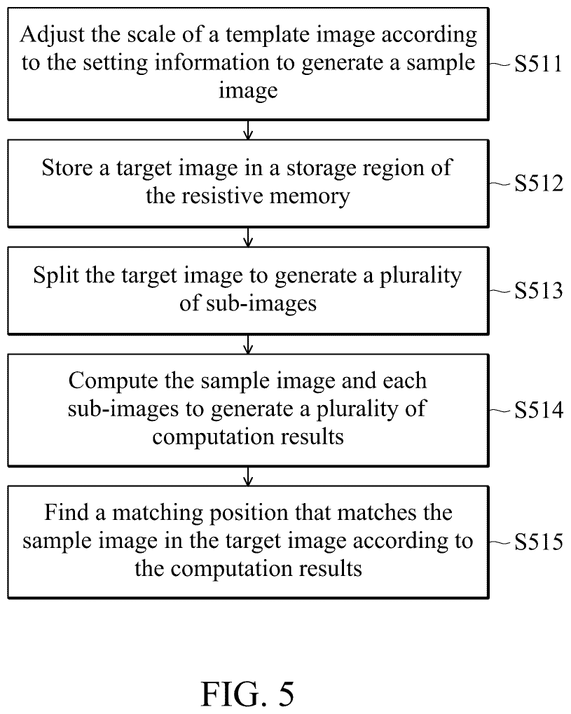

FIG. 5 is a flowchart of an exemplary embodiment of a template matching method according to various aspects of the present disclosure. The template matching method is applied in a resistive memory. The template matching method may take the form of a program code. When the program code is loaded into and executed by a machine, the machine thereby becomes the processing circuit for practicing the template matching method.

First, the scale of a template image is adjusted according to the setting information to generate a sample image (step S511). In one embodiment, step S511 is performed to access a memory to retrieve a template image and then adjust the scale of the template image according to the setting information.

A target image is stored in a storage region of the resistive memory (step S512). In one embodiment, step S512 is performed to receive the output of an image sensor, use the output of the image sensor as a target image, and store the target image in the storage region. In some embodiments, step S512 is performed to set the resistance of all resistor layers of the storage region according to all gray-levels of the target image. In other embodiments, step S512 is performed to read a memory to retrieve a target image. Additionally, step S512 may be performed to receive the output of an image sensor and uses the output of the image sensor as a target image.

The target image is split to generate a plurality of sub-images (step S513). The present disclosure does not limit how step S513 is performed to split the target image. In one embodiment, each sub-image may overlap or not overlap the adjacent sub-images. Furthermore, the number of pixels in each sub-image may be the same as the number of pixels in the template image. In this case, the number of pixels in the template image is larger than the number of pixels in the sample image.

In other embodiments, the target image is stored in a storage region of the resistive memory. In this case, step S513 is performed to split the storage region into a plurality of image regions. Each image region may overlap or not overlap the adjacent image regions. Each image region stores a portion of the target image. In one embodiment, the sizes of the image regions are the same.

The sample image and each sub-images are computed to generate a plurality of computation results (step S514). In one embodiment, step S514 is performed to multiply the sample image and each sub-image. Next, a matching position that matches the sample image is found in the target image according to the computation results (step S515). Taking FIG. 1 as an example, the control circuit 140 obtains that the image of the image region R₃ is most similar to the sample image IM_SP′ according to the computation results C[1,2,3, . . . ], C′ [1,2,3, . . . ], and C″ [1,2,3, . . . ].

It will be understood that when an element is referred to as being “on”, “connected to” or “coupled to” another element, it can be directly on, connected or coupled to the other element or intervening elements may be present. In contrast, when an element is referred to as be “directly on”, “directly connected to” or “directly coupled to” another element, there are no intervening elements present.

Template matching method, or certain aspects or portions thereof, may take the form of a program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes a processing circuit for practicing the methods.

The template matching method may also be embodied in the form of a program code transmitted over some transmission medium, such as electrical wiring or cabling, through fiber optics, or via any other form of transmission, wherein, when the program code is received and loaded into and executed by a machine such as a computer, the machine becomes a processing circuit for practicing the disclosed methods. When implemented on a general-purpose processor, the program code combines with the processor to provide a unique apparatus that operates analogously to application-specific logic circuits.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another. In the following claims, the terms “first,” “second,” etc. are used merely as labels, and are not intended to impose numerical requirements on their objects.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A processing circuit, comprising:
an image-providing device configured to provide a target image;
an adjustment device adjusting a scale of a template image to generate a sample image according to setting information;
a resistive memory comprising:
a storage region storing the target image;
a computation circuit computing the sample image and the target image to generate a plurality of computation results; and
a control circuit finding a matching position that matches the sample image in the target image according to the computation results.

2. The processing circuit as claimed in claim 1, wherein the image-providing device is an image sensor.

3. The processing circuit as claimed in claim 1, wherein the image-providing device is a memory.

4. The processing circuit as claimed in claim 1, wherein the storage region comprises a plurality of resistor layers, the target image comprises a plurality of pixels, and a resistance of each resistor layer is related to a gray-level of each pixel.

5. The processing circuit as claimed in claim 1, wherein the computation circuit splits the storage region into a plurality of image regions according to the setting information and computes the sample image with images stored in the image regions to generate the computation results.

6. The processing circuit as claimed in claim 5, wherein each image region overlaps adjacent image regions.

7. The processing circuit as claimed in claim 5, wherein the number of pixels in the image stored in each image region is the same as the number of pixels in the sample image.

8. The processing circuit as claimed in claim 5, wherein the storage region comprises a plurality of transmission lines and a plurality of resistor layers, and each resistor layer is coupled between two of the transmission lines.

9. The processing circuit as claimed in claim 8, wherein the resistive memory comprises:
a writing circuit setting resistances of the resistor layers according to gray-levels of pixels of the target image.

10. The processing circuit as claimed in claim 9, wherein the computation circuit comprises:
a sample-hold circuit coupled to the transmission lines and generating a plurality of sampling signals;
an analog-to-digital convertor circuit converting the sampling signals to generate a plurality of digital signals;
a processing circuit accumulating the digital signals to generate the computation results.

11. The processing circuit as claimed in claim 10, wherein the number of digital signals is the same as the number of pixels in the sample image.

12. The processing circuit as claimed in claim 10, further comprising:
a digital-to-analog convertor circuit converting all gray-levels of the sample image to generate a plurality of analog signals and providing the analog signals to the storage region.

13. The processing circuit as claimed in claim 11, wherein the number of pixels in the target image is larger than the number of pixels in the sample image.

14. A template matching method applied a resistive memory, comprising:
adjusting scale of a template image to generate a sample image;
storing a target image in a storage region of the resistive memory;
splitting the target image to generate a plurality of sub-images;
computing the sample image and the sub-images to generate a plurality of computation results; and
finding a matching position that matches the sample image in the target image according to the computation results.

15. The template matching method as claimed in claim 14, further comprising:
using an output of an image sensor as the target image.

16. The template matching method as claimed in claim 14, further comprising:
reading a memory to obtain the target image.

17. The template matching method as claimed in claim 14, wherein each sub-image overlaps adjacent sub-images.

18. The template matching method as claimed in claim 14, wherein the number of pixels in each sub-image is the same as the number of pixels in the sample image.

19. The template matching method as claimed in claim 14, wherein the number of pixels in the target image is larger than the number of pixels in the sample image.

20. The template matching method as claimed in claim 14, wherein the step of storing the target image in the storage region of the resistive memory comprises:
setting resistances of all resistor layers of the storage region according to gray-levels of all pixels of the target image.
